(19) United States
(12) Patent Application Publication
(10) Pub. No.: US 2023/0061844 A1
(43) Pub. Date: Mar. 2, 2023

(54) PAD STRUCTURE, DISPLAY DEVICE, AND MANUFACTURING METHOD THEREOF

(71) Applicant: Samsung Display Co., LTD., Yongin-si (KR)

(72) Inventors: Chong Sup CHANG, Yongin-si (KR); Young Seok BAEK, Yongin-si (KR); Ha Na SEO, Yongin-si (KR); Eui Kang HEO, Yongin-si (KR)

(73) Assignee: Samsung Display Co., LTD., Yongin-si (KR)

(21) Appl. No.: 17/707,294

(22) Filed: Mar. 29, 2022

(30) Foreign Application Priority Data
Aug. 30, 2021 (KR) 10-2021-0114697

(51) Int. Cl. H01L 27/15; H01L 33/24; H01L 33/38; H01L 33/44; H01L 33/00

(52) U.S. Cl. CPC H01L 27/156; H01L 33/24; H01L 33/38; H01L 33/44; H01L 33/005; H01L 2933/0016

(57) ABSTRACT

A display device includes a display area and a pad area, a first electrode and a second electrode disposed on a substrate in the display area, the first electrode and the second electrode being spaced apart from each other, a transistor disposed on the substrate in the display area, the transistor being electrically connected to the first electrode, and including a first transistor electrode and a second transistor electrode; a light emitting element disposed on the first electrode and the second electrode; and a pad structure disposed on the substrate in the pad area, the pad structure including a first pad pattern and a second pad pattern which is disposed on the first pad pattern and is electrically connected to the first pad pattern.

### CROSS-REFERENCE TO RELATED APPLICATION(S)

The application claims priority to and the benefit of Korean patent application 10-2021-0114697 under 35 U.S.C. § 119, filed in the Korean Intellectual Property Office (KIPO) on Aug. 30, 2021, the entire content of which is incorporated herein by reference.

### BACKGROUND

### 1. Technical Field

The disclosure generally relates to a pad structure, a display device, and a manufacturing method thereof.

### 2. Description of the Related Art

Recently, research and development of display devices have been continuously conducted with increased interest in information displays.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a pad structure, a display device, and a manufacturing method thereof, in which the reliability of an electrical signal may be improved, and the structural stability of an electrode configuration may be ensured.

Embodiments also provide a pad structure, a display device, and a manufacturing method thereof, in which process steps may be simplified, and thus process cost may be reduced.

In accordance with an aspect of the disclosure, there is provided a display device including a display area and a pad area, the display device may include a first electrode and a second electrode disposed on a substrate in the display area, the first electrode and the second electrode being spaced apart from each other; a transistor disposed on the substrate in the display area, the transistor being electrically connected to the first electrode, and including a first transistor electrode and a second transistor electrode; a light emitting element disposed on the first electrode and the second electrode; and a pad structure disposed on the substrate in the pad area, the pad structure including a first pad pattern and a second pad pattern disposed on the first pad pattern, the second pad pattern being electrically connected to the first pad pattern, wherein the first electrode includes a (1-1)th electrode and a (1-2)th electrode disposed on the (1-1)th electrode, the second electrode includes a (2-1)th electrode and a (2-2)th electrode disposed on the (2-1)th electrode, the first pad pattern, the first transistor electrode, and the second transistor electrode include a same material, the second pad pattern, the (1-1)th electrode, and the (2-1)th electrode include a same material, and the (1-1)th electrode and the (2-1)th electrode include a transparent conductive material.

The display device may further include a power line disposed on the substrate, the power line supplying power to the light emitting element. The (1-1)th electrode may be electrically connected to the transistor through a first contact part does not contact the (1-2)th electrode, and the (2-1)th electrode may be electrically connected to the power line through a second contact part does not contact the (2-2)th electrode.

The (1-2)th electrode and the (2-2)th electrode may include a reflective material and reflect light emitted from the light emitting element.

The display device may further include a first contact electrode electrically connecting the first electrode and the light emitting element; and a second contact electrode electrically connecting the second electrode and the light emitting element. The first contact electrode may be electrically connected to the (1-1)th electrode, and the second contact electrode may be electrically connected to the (2-1)th electrode.

The first transistor electrode, the second transistor electrode, and the first pattern may include at least one of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), aluminum (Al), and alloys thereof.

The second pad pattern may include a material different from a material of the (1-2)th electrode and a material of the (2-2)th electrode. The (1-1)th electrode, the (2-1)th electrode, and the second pad pattern may include at least one of Indium Tin Oxide (ITO), Indium Zinc Oxide (IZO), and Indium Tin Zinc Oxide (ITZO).

The second pad pattern may cover a side surface of the first pad pattern such that the first pad pattern is not exposed.

The display device may further include a third pad pattern electrically connected to the second pad pattern, the third pad pattern being disposed on the second pad pattern; and a fourth pad pattern electrically connected to the third pattern, the fourth pad pattern being disposed on the third pad pattern. The first contact electrode and the third pad pattern may include a same material, and the second contact electrode and the fourth pad pattern may include a same material.

The display device may further include an alignment area including an area in which the light emitting element is disposed; and a non-alignment area including an area in which the light emitting element is not disposed. The first electrode and the second electrode may extend in a first direction. The alignment area and the non-alignment area may overlap each other in the first direction. The (1-1)th electrode and the (1-2)th electrode may overlap each other in the alignment area and may not overlap each other in the non-alignment area in a plan view. The (2-1)th electrode and the (2-2)th electrode may overlap each other in the alignment area and may not overlap each other in the non-alignment area in a plan view.

The display device may further include an open area disposed in the non-alignment area, and the first electrode and the second may not be disposed in the open area.

In accordance with another aspect of the disclosure, there is provided a pad structure, the pad structure may include: a first pad pattern disposed on a substrate; and a second pad pattern electrically connected to the first pad pattern, the second pad pattern being disposed on the first pad pattern, the second pad pattern includes a transparent conductive material and covers a side surface of the first pad pattern such that the first pad pattern is not exposed.

The pad structure may further include a third pad pattern electrically connected to the second pad pattern, the third pad pattern being disposed on the second pad pattern; and a fourth pad pattern electrically connected to the third pattern, the fourth pad pattern disposed on the third pad pattern. The third pad pattern and the fourth pad pattern may include a transparent conductive material.

In accordance with still another aspect of the disclosure, there is provided a method of manufacturing a display device including a display area and a pad area, the method may include disposing a lower insulating layer on a substrate; disposing a first transistor electrode and a second transistor electrode on the lower insulating layer in the display area; disposing, a first pad pattern on the lower insulating layer in the pad area; disposing a base lower electrode and a base upper electrode on the lower insulating layer, removing at least part of each of the base lower electrode and the base upper electrode; and disposing a light emitting element on the substrate, wherein, in the removing of the at least the portion of each of the base lower electrode and the base upper electrode, includes: forming a first photoresist layer in a blocking area corresponding to a blocking part of a mask, forming a second photoresist layer in a half-tone area corresponding to a half-tone part of the mask, exposing the base upper electrode in a full-tone area corresponding to a full-tone part of the mask; a first etching step of etching the base lower electrode and the base upper electrode in the full-tone area; and a second etching step of etching the base upper electrode in the half-tone area, and the disposing of the first transistor electrode and the second transistor electrode and the disposing of the first pad pattern are performed through a same process, and the first etching step includes disposing a second pad pattern on the first pad pattern, the second pad pattern being electrically connected to the first pad pattern.

The second etching step may include disposing a lower electrode in the display area. The method may further include disposing a base contact electrode on the lower electrode after the second etching step, and simultaneously etching the base contact electrode and the lower electrode.

The simultaneously etching of the base contact electrode and the lower electrode may include providing an open area in which the lower electrode is not disposed.

The disposing of the base lower electrode and the base upper electrode may include disposing the base lower electrode to cover the first pad pattern. In the first etching step, at least part of the base lower electrode disposed on a side surface of the first pad pattern may not be etched.

The second pad pattern may cover the first pad pattern such that influence of the second etching step on the first pad pattern is decreased.

The disposing of the first transistor electrode and the second transistor electrode and the disposing of the first pad pattern may be performed through a same process.

The disposing of the base lower electrode may include electrically connecting the transistor and the base lower electrode to each other.

The disposing of the light emitting element may include providing, on the substrate, an ink including the light emitting element and a solvent, forming an electric field by applying an electrical signal to the lower electrode, and arranging the light emitting element in accordance with the electric field.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1 and 2 are schematic and sectional views illustrating a light emitting element in accordance with an embodiment.

FIG. 3 is a schematic plan view illustrating a display device in accordance with an embodiment.

FIG. 4 is a schematic plan view illustrating a pixel in accordance with an embodiment.

FIG. 5 is a schematic sectional view taken along line I-I′ shown in FIG. 4.

FIG. 6 is a schematic sectional view taken along line II-II' shown in FIG. 3.

FIGS. 7, 9, 10, 12, 13, 15, 17, and 19 are schematic sectional views illustrating a manufacturing method of the display device in accordance with an embodiment.

FIGS. 8, 11, 14, 16, and 18 are schematic plan views illustrating the manufacturing method of the display device in accordance with an embodiment.

### DETAILED DESCRIPTION OF THE EMBODIMENTS

Embodiments disclosed in the specification are provided only for illustrative purposes and for full understanding of the scope of the disclosure by those skilled in the art. However, the disclosure is not limited to the embodiments, and it should be understood that the disclosure includes modification examples or change examples without departing from the spirit and scope of the present disclosure.

The terms used in the specification has been selected as general terms currently widely used if possible considering the functions in the disclosure, but they may depend on the intentions of those skilled in the art, practice, the appearance of new technologies, etc. In addition, specific cases use the terms selected arbitrarily by the applicant and in these cases, their meaning will be described when describing corresponding disclosures. Thus, it should be noted that the terms used in the specification should be construed on the basis of their actual meanings and contents through the specification, not just names thereof.

The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Since the disclosure may have diverse modified embodiments, various embodiments are illustrated in the drawings and are described in the detailed description. Advantages and features of the embodiments, and implementation methods thereof will be clarified through following embodiments described with reference to the accompanying drawings. The disclosure may, however, be embodied in many different forms and should not be construed as limited to the embodiments set forth herein.

Reference will now be made in detail to embodiments, examples of which are illustrated in the accompanying drawings, wherein like reference numerals refer to like elements throughout, and repeated description thereof will be omitted.

It will be understood that although the terms “first,” “second,” etc. may be used herein to describe various components, these components should not be limited by these terms. These terms are only used to distinguish one element from another. For instance, a first element discussed below could be termed a second element without departing from the teachings of the disclosure. Similarly, the second element could also be termed the first element.

An expression used in the singular encompasses the expression of the plural, unless it has a clearly different meaning in the context.

It will be further understood that when the terms “comprises,” “comprising,” “includes” and/or “including”, “have” and/or “having” are used in this specification, they or it may specify the presence of stated features, integers, steps, operations, elements and/or components, but do not preclude the presence or addition of other features, integers, steps, operations, elements, components, and/or any combination thereof.

When a layer, film, region, substrate, or area, or element is referred to as being “on” another layer, film, region, substrate, or area, or element, it may be directly on the other film, region, substrate, or area, or element, or intervening films, regions, substrates, or areas, or elements may be present therebetween. Conversely, when a layer, film, region, substrate, or area, or element, is referred to as being “directly on” another layer, film, region, substrate, or area, or element, intervening layers, films, regions, substrates, or areas, may be absent therebetween. Further when a layer, film, region, substrate, or area, or element, is referred to as being “below” another layer, film, region, substrate, or area, or element, it may be directly below the other layer, film, region, substrate, or area, or element, or intervening layers, films, regions, substrates, or areas, or elements, may be present therebetween. Conversely, when a layer, film, region, substrate, or area, or element, is referred to as being “directly below” another layer, film, region, substrate, or area, or element, intervening layers, films, regions, substrates, or areas, or elements may be absent therebetween. Further, “over” or “on” may include positioning on or below an object and does not necessarily imply a direction based upon gravity.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Further, in the specification, the phrase “in a plan view” means when an object portion is viewed from above, and the phrase “in a schematic cross-sectional view” means when a schematic cross-section taken by vertically cutting an object portion is viewed from the side.

Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first element may directly or indirectly oppose a second element. In a case in which a third element intervenes between the first and second element, the first and second element may be understood as being indirectly opposed to one another, although still facing each other. When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

When an embodiment may be implemented differently, a specific process order may be performed differently from the described order. For example, two consecutively described processes may be performed substantially at the same time or performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that when a layer, region, or element is referred to as being “connected to” or “coupled to” another layer, region, or element, it can be directly connected or coupled to the other layer, region, or element or intervening layers, regions, or elements may be present. For example, as used herein, when a layer, region, or element is referred to as being “electrically connected to” another layer, region, or element, it can be directly electrically connected to the other layer, region, or element or intervening layers, intervening regions, or intervening elements may be present.

Also, when an element is referred to as being “in contact” or “contacted” or the like to another element, the element may be in “electrical contact” or in “physical contact” with another element; or in “indirect contact” or in “direct contact” with another element.

Unless otherwise defined, all terms (including technical and scientific terms) used herein have the same meaning as commonly understood by one of ordinary skill in the art to which embodiments pertain. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, the disclosure will be described in detail with reference to the accompanying drawings.

The drawings attached to the specification are provided to easily explain the disclosure, and the shapes shown in the drawings may be exaggerated and displayed as necessary to help understanding of the disclosure, and thus the disclosure is not limited to the drawings.

In the specification, when it is determined that a detailed description of a known configuration or function related to the disclosure may obscure the gist of the present disclosure, a detailed description thereof will be omitted as necessary.

The disclosure generally relates to a pad structure, a display device, and a manufacturing method thereof. Hereinafter, a pad structure, a display device, and a manufacturing method thereof in accordance with embodiments of the disclosure will be described with reference to the accompanying drawings.

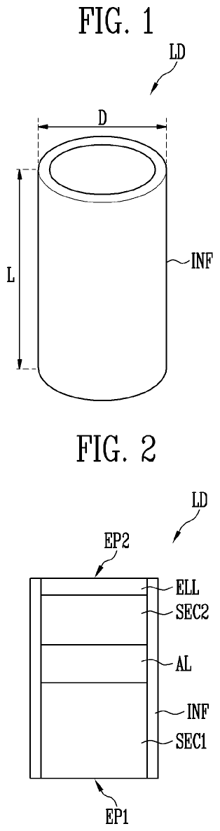

FIGS. 1 and 2 illustrate a light emitting element LD included in a display device in accordance with an embodiment. FIGS. 1 and 2 are schematic and sectional views illustrating a light emitting element in accordance with an embodiment.

Referring to FIGS. 1 and 2, the light emitting element LD may include a first semiconductor layer SEC1, a second semiconductor layer SEC2, and an active layer AL interposed between the first semiconductor layer SEC1 and the second semiconductor layer SEC2. The light emitting element LD may further include an electrode layer ELL. In accordance with an embodiment, the first semiconductor layer SEC1, the active layer AL, the second semiconductor layer SEC2, and the electrode layer ELL may be sequentially stacked or disposed along a length L direction of the light emitting element LD.

The light emitting element LD may include a first end portion EP1 and a second end portion EP2. The first semiconductor layer SEC1 may be adjacent to the first end portion EP1 of the light emitting element LD. The second semiconductor layer SEC2 and the electrode layer ELL may be adjacent to the second end portion EP2 of the light emitting element LD.

In accordance with an embodiment, the light emitting element LD may have a pillar shape. The pillar shape may be a shape extending extend in the length L direction thereof, such as a cylinder or a polyprism. For example, a length L of the light emitting element LD may be greater than a diameter D (or a width of a cross-section) of the light emitting element LD. The shape of a section of the light emitting element LD may include a rod-like shape or bar-like shape, but the disclosure is not limited thereto.

The light emitting element LD may have a size of nanometer scale to micrometer scale. For example, each of the diameter D (or width) and the length L of the light emitting element LD may have a size of nanometer scale to micrometer scale, but the disclosure is not limited thereto.

The first semiconductor layer SEC1 may be a first conductivity type semiconductor layer. For example, the first semiconductor layer SEC1 may include an N-type semiconductor layer. In an example, the first semiconductor layer SEC1 may include any one semiconductor material among InAlGaN, GaN, AlGaN, InGaN, AlN, and InN, and include an N-type semiconductor layer doped with a first conductivity type dopant such as Si, Ge or Sn. However, the material constituting the first semiconductor layer SEC1 is not limited thereto. The first semiconductor layer SEC1 may be configured with various materials.

The active layer AL may be disposed on the first semiconductor layer SEC1. The active layer AL may be disposed between the first semiconductor layer SEC1 and the second semiconductor layer SEC2.

The active layer AL may include any one of AlGaInP, AIGaP, AlInGaN, InGaN, and AIGaN. For example, in a case that the active layer AL is to output red light, the active layer AL may include AlGaInP and/or InGaN. In a case that the active layer AL is to output green light or blue light, the active layer AL may include InGaN. However, the active layer AL is not limited to the above-described example.

The active layer AL may be a single-quantum well structure or a multi-quantum well structure.

The second semiconductor layer SEC2 may formed on the active layer AL, and may include a semiconductor layer having a type different from that of the first semiconductor layer SEC1. For example, the second semiconductor layer SEC2 may include a P-type semiconductor layer. In an example, the second semiconductor layer SEC2 may include at least one semiconductor material among InAlGaN, GaN, AlGaN, InGaN, AlN, and InN, and include a P-type semiconductor layer doped with a second conductivity type dopant such as Mg. However, the material constituting the second semiconductor layer SEC2 is not limited thereto. For example, the second semiconductor layer SEC2 may be configured with various materials.

The electrode layer ELL may be formed on the second semiconductor layer SEC2. The electrode layer ELL may include metal or metal oxide. In an example, the electrode layer ELL may include at least one of Cr, Ti, Al, Au, Ni, ITO, IZO, ITZO, and any oxide or alloy thereof.

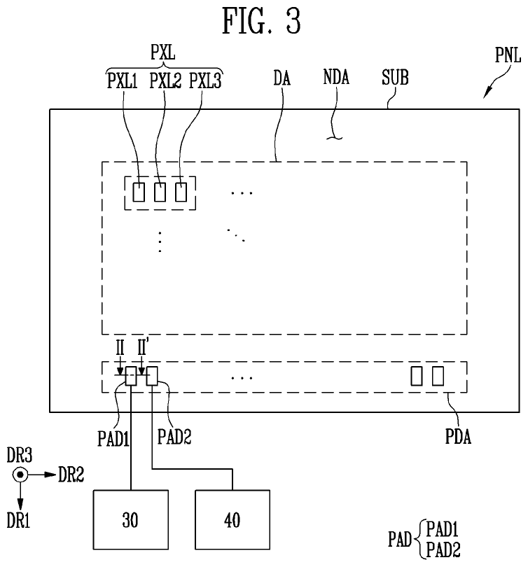

In a case that a voltage which is a threshold voltage or more is applied to both ends of the light emitting element LD, electron-hole pairs are combined in the active layer AL, and the light emitting element LD may emit light. Accordingly, light emission of the light emitting element LD may be controlled, such that the light emitting element LD may be used as a light source for various light emitting devices, including a display device DD as shown in FIG. 3.

The light emitting element LD may include an insulative film INF provided or disposed on a surface thereof. The insulative film INF may be a single film or multiple films.

The insulative film INF may expose end portions of the light emitting element LD which have different polarities. For example, the insulative film INF may expose a portion of each of the first semiconductor layer SEC1 disposed adjacent to the first end portion EP1 and the electrode layer ELL disposed adjacent to the second end portion EP2.

The insulative film INF may include any one of silicon oxide (SiOₓ), silicon nitride (SiNₓ), silicon oxynitride (SiOₓN_{y}), aluminum oxide (AlOₓ), and titanium oxide (TiOₓ). However, the insulative film INF is not limited to a specific example.

The insulative film INF may ensure the electrical stability of the light emitting element. For example, the insulative film INF may prevent occurrence of an unwanted short circuit between light emitting elements LD even when the light emitting elements LD are disposed close to each other.

In accordance with an embodiment, the light emitting element LD may further include additional component. For example, the light emitting element LD may further include a phosphor layer, an active layer, a semiconductor layer, and/or an electrode layer.

FIG. 3 is a schematic plan view illustrating a display device in accordance with an embodiment.

FIG. 3 relates to a display device using the light emitting element LD as a light source, and illustrates a display panel PNL provided or disposed in the display device in accordance with an embodiment.

Referring to FIG. 3, the display device in accordance with the embodiment of the disclosure may include the display panel PNL, a scan driver 30, and a data driver 40.

A substrate SUB may constitute a base member of the display panel PNL, and may be a rigid or flexible substrate or film. However, the substrate SUB is not necessarily limited to the above-described example.

The display panel PNL and the substrate SUB may include a display area DA and a non-display area NDA adjacent to the display area DA.

Pixels PXL may be arranged or disposed in the display area DA. Each pixel PXL may include the light emitting element LD. The pixel PXL may emit light based on a signal provided from the scan driver 30 and/or a signal provided from the data driver 40.

The pixels PXL may be arranged or disposed in the display area DA according to a stripe array, a PENTILE® array, or the like. However, the embodiment is not limited thereto, and the pixels PXL may be variously arranged or disposed in the display area DA by using various methods.

In accordance with an embodiment, the pixels PXL emitting lights of different colors may be disposed in the display area DA. In an example, the pixel PXL may include a first pixel PXL1 emitting light of a first color, a second pixel PXL2 emitting light of a second color, and a third pixel PXL3 emitting light of a third color. At least one first pixel PXL1, a least one second pixel PXL2, and at least one third pixel PXL3 may be disposed adjacent to each other, and may constitute one pixel to emit lights of various colors. For example, each of the first to third pixels PXL1, PXL2, and PXL3 may be a sub-pixel emitting light of a predetermined color. In accordance with an embodiment, the first pixel PXL1 may be a red pixel emitting light of red, the second pixel PXL2 may be a green pixel emitting light of green, and the third pixel PXL3 may be a blue pixel emitting light of blue.

In accordance with an embodiment, the first pixel PXL1, the second pixel PXL2, and the third pixel PXL3 may respectively have, as light sources, a light emitting element of the first color, a light emitting element of the second color, and a light emitting element of the third color, such that the light emitting elements may respectively emit lights of the first color, the second color, and the third color. In another embodiment, the first pixel PXL1, the second pixel PXL2, and the third pixel PXL3 may have light emitting elements emitting light of a same color, and may include color conversion layers and/or color filter layers of different colors disposed on respective light emitting elements to respectively emit lights of the first color, the second color, and the third color. However, the color, kind, and/or number of pixels PXL constituting each pixel are not limited thereto. For example, the color of light emitted by each pixel PXL may be variously changed.

The scan driver 30 may output a scan signal. The data driver 40 may output a data signal. Each of the scan driver 30 and the data driver 40 may be electrically connected to lines of the display panel PNL. The scan driver 30 and the data driver 40 may be located or disposed at outside of or adjacent to the display panel PNL. However, the disclosure is not limited thereto. In an embodiment, at least one of the scan driver 30 and the data driver 40 may be located or disposed at the inside of the display panel PNL.

Various types of lines, a pad PAD, and/or a built-in circuit, electrically connected to the pixel PXL of the display area DA may be disposed in the non-display area NDA.

A pad area PDA may be disposed in the non-display area NDA. The pad area PDA may be located or disposed at one or a side of the display area DA. Although a case that the pad area PDA disposed adjacent to the display area DA at a lower side of the display area DA is illustrated in FIG. 3, the disclosure is not limited thereto.

The pad PAD may be disposed in the pad area PDA. The pad PAD may include a first pad PAD1 and a second pad PAD2. The first pad PAD1 may be a gate pad, and the second pad PAD2 may be a data pad. The first pad PAD1 may be electrically connected to the scan driver 30. The scan signal provided from the scan driver 30 may be transferred to a scan line electrically connected to the pixel PXL via the first pad PAD1. The second pad PAD2 may be electrically connected to the data driver 40. The data signal provided from the data driver 40 may be transferred to a data line electrically connected to the pixel PXL via the second pad PAD2.

In accordance with an embodiment, the pad PAD may be designated as a pad structure.

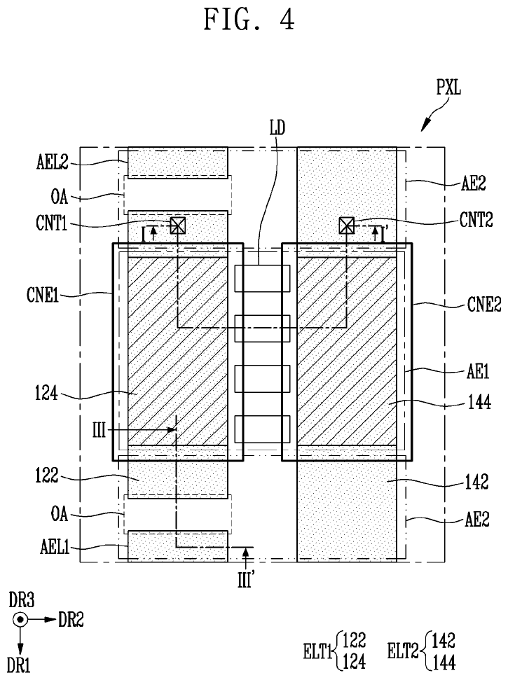

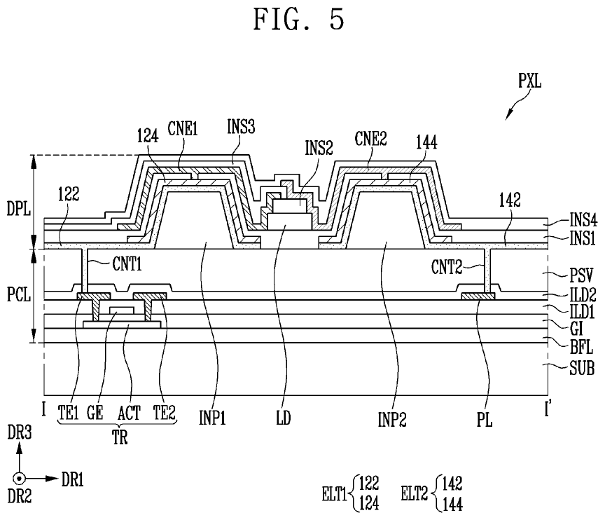

Hereinafter, a pixel PXL in accordance with an embodiment of the disclosure will be described with reference to FIGS. 4 and 5.

FIG. 4 is a schematic plan view illustrating a pixel in accordance with an embodiment. The pixel PXL shown in FIG. 4 may be any one of the first to third pixels PXL1, PXL2, and PXL3.

Referring to FIG. 4, the pixel PXL may include a light emitting element LD, a first electrode ELT1, a second electrode ELT2, a first adjacent electrode AEL1, a second adjacent electrode AEL2, a first contact part CNT1, a second contact part CNT2, a first contact electrode CNE1, and a second contact electrode CNE2. In an example, the first electrode ELT1 may include a (1-1)th electrode 122 and a (1-2)th electrode 124, and the second electrode ELT2 may include a (2-1)th electrode 142 and a (2-2)th electrode 144.

The pixel PXL may include an alignment area AE1 and a non-alignment area AE2. The alignment area AE1 may be an area where the light emitting element LD is disposed. For example, light emitting elements LD may be arranged or disposed in parallel along a first direction DR1 in the alignment area AE1. The non-alignment area AE2 may be an area adjacent to the alignment area AE1 and may be an area where the light emitting element LD is not disposed.

In FIG. 4, the alignment area AE1 is indicated by an alternated long line and two short dashes, and the non-alignment area AE2 is indicated by an alternate long line and two dots.

In accordance with an embodiment, the alignment area AE1 and the non-alignment area AE2 may be alternately disposed. For example, the alignment area AE1 may be disposed between adjacent non-alignment areas AE2. One or a side of the alignment area AE1 may be adjacent to a first non-alignment area AE2 where a first adjacent electrode AEL1 is disposed, and other or another side of the alignment area AE1 may be adjacent to a second non-alignment area AE2 where a second adjacent electrode AEL2 is disposed.

In accordance with an embodiment, the alignment area AE1 and the non-alignment area AE2 may be spaced apart from each other along the first direction DR1. The alignment area AE1 and the non-alignment area AE2 may overlap each other along the first direction DR1. The non-alignment area AE2 may not overlap with the light emitting element LD along a second direction DR2. The non-alignment area AE2 may overlap the light emitting element LD along the first direction DR1.

In accordance with an embodiment, the alignment area AE1 may overlap with the (1-2)th electrode 124 and the (2-2)th electrode 144. The non-alignment area AE2 may overlap with the (1-1)th electrode 122 and the (2-1)th electrode 142.

For example, the alignment area AE1 may include an area where the (1-1)th electrode 122 and the (1-2)th electrode 124 overlap with each other and an area where the (2-1)th electrode 142 and the (2-2)th electrode 144 overlap with each other. The non-alignment area AE2 may include an area where only the (1-1)th electrode 122 is disposed and an area where only the (2-1)th electrode 142 is disposed.

In accordance with an embodiment, an open area OA may be disposed in the non-alignment area AE2. The open area OA may overlap the non-alignment area AE2 when viewed in a plan view.

The open area OA may be an area where electrode components adjacent to the first electrode ELT1 are electrically separated from each other such that a sub-pixel included in the pixel PXL may be individually configured. For example, the light emitting element LD included in the pixel PXL shown in FIG. 4 may emit light based on an anode signal provided from the first electrode ELT1. The first electrode ELT1 may be spaced apart from the first adjacent electrode AEL1 that disposed at a lower side of the first electrode ELT1 with a first open area OA interposed therebetween, and the second adjacent electrode AEL2 that disposed at an upper side of the first electrode ELT1 with a second open area OA interposed therebetween.

Multiple light emitting elements LD may be provided. For example, the light emitting elements LD may be arranged or disposed in parallel along the first direction DR1. However, the arrangement of the light emitting elements LD is not limited thereto.

The light emitting element LD may be disposed between electrodes that serving as alignment electrodes. For example, the light emitting element LD may be disposed between the first electrode ELT1 and the second electrode ELT2. The light emitting element LD may be disposed on the first electrode ELT1 and the second electrode ELT2. At least a portion of the light emitting element LD may be disposed between the first electrode ELT1 and the second electrode ELT2 when viewed in a plan view.

The light emitting element LD may be electrically connected to the first electrode ELT1 through the first contact electrode CNE1. The light emitting element LD may be electrically connected to the second electrode ELT2 through the second contact electrode CNE2.

The first electrode ELT1 may extend in the first direction DR1. The first electrode ELT1 may be spaced apart from the second electrode ELT2 in the second direction DR2. The second direction DR2 may intersect (or be non-parallel to) the first direction DR1.

Referring to FIG. 5, the first electrode ELT1 may be electrically connected to a transistor TR included in a pixel circuit part PCL through the first contact part CNT1.

The first electrode ELT1 may be electrically connected to the first contact electrode CNE1. The first electrode ELT1 may be electrically connected to the light emitting element LD through the first contact electrode CNE1.

The first electrode ELT1 may be multi-layered. For example, as described above, the first electrode ELT1 may include the (1-1)th electrode 122 and the (1-2)th electrode 124.

The (1-1)th electrode 122 may be a lower layer of the first electrode ELT1. The (1-2)th electrode 124 may be an upper layer of the first electrode ELT1. In accordance with an embodiment, the (1-1)th electrode 122 and the (1-2)th electrode 124 may overlap with each other when viewed in a plan view.

In accordance with an embodiment, the (1-1)th electrode 122 may be disposed throughout the alignment area AE1 and the non-alignment area AE2. For example, a portion of the (1-1)th electrode 122 may be arranged or disposed in the alignment area AE1, and another portion of the (1-1)th electrode 122 may be arranged or disposed in the non-alignment area AE2.

In accordance with an embodiment, the (1-2)th electrode 124 may be disposed in the alignment area AE1, and may not be disposed in the non-alignment area AE2.

The second electrode ELT2 may extend in the first direction DR1. The second electrode ELT2 may be spaced apart from the first electrode ELT1 in the second direction DR2.

As shown in FIG. 5, the second electrode ELT2 may be electrically connected to a power line PL. included or disposed in the pixel circuit part PCL through the second contact part CNT2.

The second electrode ELT2 may be electrically connected to the second contact electrode CNE2. The second electrode ELT2 may be electrically connected to the light emitting element LD through the second contact electrode CNE2.

The second electrode ELT2 may be multi-layered. For example, as described above, the second electrode ELT2 may include the (2-1)th electrode 142 and the (2-2)th electrode 144.

The (2-1)th electrode 142 may be a lower layer of the second electrode ELT2. The (2-2)th electrode 144 may be an upper layer of the second electrode ELT2. In accordance with an embodiment, the (2-1)th electrode 142 and the (2-2)th electrode 144 may overlap with each other when viewed in a plan view.

In accordance with an embodiment, the (2-1)th electrode 142 may be disposed throughout the alignment area AE1 and the non-alignment area AE2. For example, a portion of the (2-1)th electrode 142 may be arranged or disposed in the alignment area AE1, and another portion of the (2-1)th electrode 142 may be arranged or disposed in the non-alignment area AE2.

In accordance with an embodiment, the (2-2)th electrode 144 may be disposed in the alignment area AE1, and may not be disposed in the non-alignment area AE2.

The first adjacent electrode AEL1 may be spaced part from the first electrode ELT1 in the first direction DR1 with the first open area OA interposed therebetween. The first adjacent electrode AEL1 may be spaced apart from the second electrode ELT2 in the second direction DR2.

The first adjacent electrode AEL1 may be an alignment electrode for a light emitting element LD disposed in an adjacent sub-pixel in the first direction DR1 with respect to the light emitting element LD disposed between the first electrode ELT1 and the second electrode ELT2. For example, the first adjacent electrode AEL1 and a portion of the second electrode ELT2 may serve as an alignment electrode for a pixel PXL adjacent to a lower side of the pixel PXL shown in FIG. 4.

The second adjacent electrode AEL2 may be spaced apart from the first electrode ELT1 in the first direction DR1 with the second open area OA interposed therebetween. The second adjacent electrode AEL2 may be spaced part from the second electrode ELT2 in the second direction DR2.

The second adjacent electrode AEL2 may be an alignment electrode for a light emitting element LD disposed in an adjacent pixel in the first direction DR1 with respect to the light emitting element LD disposed between the first electrode ELT1 and the second electrode ELT2. For example, the second adjacent electrode AEL2 and a portion of the second electrode ELT2 may serve as an alignment electrode for a pixel PXL adjacent to an upper side of the pixel PXL shown in FIG. 4.

FIG. 5 is a schematic view illustrating a sectional of a pixel PXL in accordance with an embodiment. FIG. 5 is a schematic sectional view taken along line I-I′ shown in FIG. 4.

Referring to FIG. 5, the pixel PXL may include a substrate SUB, a pixel circuit part PCL, and a display element part DPL.

The substrate SUB may be provided as a base surface such that the pixel circuit part PCL and the display element part DPL may be disposed on the substrate SUB.

The pixel circuit part PCL may be disposed on the substrate SUB. The pixel circuit part PCL may include a buffer layer BFL, a transistor TR, a gate insulating layer GI, a first interlayer insulating layer ILD1, a second interlayer insulating layer ILD2, a power line PL, a protective layer PSV, a first contact part CNT1, and a second contact part CNT2.

The buffer layer BFL may be disposed on the substrate SUB. The buffer layer BFL may prevent an impurity from being diffused from the outside. The buffer layer BFL may include any one of silicon nitride (SiNₓ), silicon oxide (SiOₓ), silicon oxynitride (SiOₓN_{y}), and aluminum oxide (AlOₓ).

The transistor TR may be a thin film transistor. In accordance with an embodiment, the transistor TR may be a driving transistor.

The transistor TR may be electrically connected to a light emitting element LD. The transistor TR may be electrically connected to a first electrode ELT1 through the first contact part CNT1.

The transistor TR may include an active layer ACT, a first transistor electrode TE1, a second transistor electrode TE2, and a gate electrode GE.

The active layer ACT may include a semiconductor layer. The active layer ACT may be disposed on the buffer layer BFL. The active layer ACT may include at least one of poly-silicon, Low Temperature Polycrystalline Silicon (LTPS), amorphous silicon, and an oxide semiconductor.

The active layer ACT may include a first contact region contacting (e.g., directly contacting) the first transistor electrode TE1, and a second contact region contacting (e.g., directly contacting) the second transistor electrode TE2. The first contact region and the second contact region may correspond to a semiconductor pattern doped with an impurity. A region between the first contact region and the second contact region may be a channel region. The channel region may correspond to an intrinsic semiconductor pattern not doped with the impurity.

The gate electrode GE may be disposed on the gate insulating layer GI. The gate electrode GE may be disposed to overlap the channel region of the active layer ACT. For example, the gate electrode GE may be disposed on the channel region of the active layer ACT with the gate insulating layer GI interposed therebetween.

In accordance with an embodiment, the gate electrode GE may include molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), aluminum (Al), and/or alloys thereof.

The gate insulating layer GI may be disposed to overlap or cover the active layer ACT. The gate insulating layer GI may include an inorganic material. In an example, the gate insulating layer GI may include any one of silicon nitride (SiNₓ), silicon oxide (SiOₓ), silicon oxynitride (SiOₓN_{y}), and aluminum oxide (AlOₓ).

The first interlayer insulating layer ILD1 may be disposed to overlap or cover the gate electrode GE. Like the gate insulating layer GI, the first interlayer insulating layer ILD1 may include at least one of silicon nitride (SiNₓ), silicon oxide (SiOₓ), silicon oxynitride (SiOₓN_{y}), and aluminum oxide (AlOₓ).

The first transistor electrode TE1 and the second transistor electrode TE2 may be located or disposed on the first interlayer insulating layer ILD1. The first transistor electrode TE1 may contact (e.g., directly contact) the first contact region of the active layer ACT while penetrating the gate insulating layer GI and the first interlayer insulating layer ILD1. The second transistor electrode TE2 may contact (e.g., directly contact) the second contact region of the active layer ACT while penetrating the gate insulating layer GI and the first interlayer insulating layer ILD1. In an example, the first transistor electrode TE1 may be a drain electrode, and the second transistor electrode TE2 may be a source electrode. However, the disclosure is not limited thereto.

In accordance with an embodiment, the first transistor electrode TE1 and the second transistor electrode TE2 may include a conductive material. For example, the first transistor electrode TE1 and the second transistor electrode TE2 may include metals such as molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), aluminum (Al), and/or alloys thereof. In an example, the first transistor electrode TE1 and the second transistor electrode TE2 may be multi-layered including titanium (Ti) and copper (Cu).

The second interlayer insulating layer ILD2 may be located or disposed overlapping or covering the first transistor electrode TE1 and the second transistor electrode TE2. Like the first interlayer insulating layer ILD1 and the gate insulating layer GI, the second interlayer insulating layer ILD2 may include an inorganic material. The inorganic material may include at least one of the materials exemplified as the material constituting the first interlayer insulating layer ILD1 and the gate insulating layer GI, e.g., silicon nitride (SiNₓ), silicon oxide (SiOₓ), silicon oxynitride (SiOₓN_{y}), and aluminum oxide (AlOₓ).

The power line PL may be disposed on the first interlayer insulating layer ILD1. The power line PL may be electrically connected to a second electrode ELT2 through the second contact part CNT2 penetrating the protective layer PSV and the second interlayer insulating layer ILD2.

The protective layer PSV may be located or disposed on the second interlayer insulating layer ILD2. The protective layer PSV maybe provided including an organic insulating layer, an inorganic insulating layer, or the organic insulating layer disposed on the inorganic insulating layer. In accordance with an embodiment, the first contact part connected to an area of the first transistor electrode TE1 and the second contact part CNT2 connected to an area of the power line PL may be formed or disposed in the protective layer PSV.

The display element part DPL may be disposed on the pixel circuit part PCL. The display element part DPL may include a first insulating pattern INP1, a second insulating pattern INP2, the first electrode ELT1, the second electrode ELT2, a first insulating layer INS1, the light emitting element LD, a second insulating layer INS2, a first contact electrode CNE1, a third insulating layer INS3, a second contact electrode CNE2, and a fourth insulating layer INS4. In accordance with an embodiment, as described above, the first electrode ELT1 may include a (1-1)th electrode 122 and a (1-2)th electrode 124, and the second electrode ELT2 may include a (2-1)th electrode 142 and a (2-2)th electrode 144.

Referring to FIG. 5, the first insulating pattern INP1 and the second insulating pattern INP2 may protrude in a thickness direction of the substrate SUB (e.g., a third direction DR3). The first insulating pattern INP1 and the second insulating pattern INP2 may surround or adjacent to an area where the light emitting element LD may be disposed.

The (1-2)th electrode 124 may be arranged or disposed on the first insulating pattern INP1, and the (2-2)th electrode 144 may be arranged or disposed on the second insulating pattern INP2. Accordingly, the (1-2)th electrode 124 and the (2-2)th electrode 144 may reflect light from the light emitting element LD in a display direction of the display panel PNL (e.g., the third direction DR3). Accordingly, the light efficiency of the pixel PXL may be improved.

The first electrode ELT1 may be disposed on the protective layer PSV. The first electrode ELT1 may electrically connect the transistor TR and the first contact electrode CNE1 to each other.

The (1-1)th electrode 122 may be disposed on the protective layer PSV. In accordance with an embodiment, a portion of the (1-1)th electrode 122 may be disposed on the first insulating pattern INP1.

The (1-1)th electrode 122 may be electrically connected to the transistor TR through the first contact part CNT1. In an example, the (1-1)th electrode 122 may provide an anode signal to the first contact electrode CNE1. In accordance with an embodiment, the first contact part CNT1 may not overlap the (1-2)th electrode 124 when viewed in a plan view. For example, the first contact part CNT1 may overlap with a portion of the (1-1)th electrode 122 where the (1-2)th electrode 124 is not disposed when viewed in a plan view. The first contact part CNT1 may not contact (e.g., directly contact) the (1-2)th electrode 124.

In accordance with an embodiment, the (1-1)th electrode 122 may be electrically connected to the (1-2)th electrode 124. The (1-1)th electrode 122 may be electrically connected to the first contact electrode CNE1 through the (1-2)th electrode 124. However, the (1-1)th electrode 122 is not limited thereto. For example, the (1-1)th electrode 122 may be electrically connected to the first contact electrode CNE1 through a contact hole formed in the first insulating layer INS1 and the contact hole may not contact (e.g., directly contact) the (1-2)th electrode 124.

The (1-2)th electrode 124 may be disposed on the (1-1)th electrode 122. The (1-2)th electrode 124 may overlap the (1-1)th electrode 122 when viewed in a plan view. A portion of the (1-2)th electrode 124 may be disposed on the first insulating pattern INP1. Accordingly, the (1-2)th electrode 124 may serve as a reflective partition wall with respect to the light emitting element LD.

The (1-2)th electrode 124 may electrically connect the first electrode ELT1 and the first contact electrode CNE1 to each other. For example, a portion of the (1-2)th electrode 124 may contact (e.g., directly contact) the (1-1)th electrode 122, and another portion of the (1-2)th electrode 124 may be contact (e.g., directly contact) to the first contact electrode CNE1 through a contact hole formed in the first insulating layer INS1. However, the (1-2)th electrode 124 is not limited thereto. For example, a portion of the (1-2)th electrode 124 c may contact (e.g., directly contact) the (1-1)th electrode 122, and the (1-1)th electrode 122 and the first contact electrode CNE1 may contact (e.g., directly contact) each other through a contact hole formed in the first insulating layer INS1.

The second electrode ELT2 may be provided on the protective layer PSV. The second electrode ELT2 may electrically connect the power line PL and the second contact electrode CNE2 to each other.

The (2-1)th electrode 142 may be disposed on the protective layer PSV. In accordance with an embodiment, a portion of the (2-1)th electrode 142 may be disposed on the second insulating pattern INP2.

The (2-1)th electrode 142 may be electrically connected to the power line PL through the second contact part CNT2. In an example, the (2-1)th electrode 142 may provide a cathode signal to the second contact electrode CNE2. For example, the second contact part CNT2 may overlap a portion of the (2-1)th electrode 142 where the (2-2)th electrode 144 is not disposed when viewed in a plan view. The second contact part CNT2 may not contact (e.g., directly contact) the (2-2)th electrode 144.

In accordance with an embodiment, the (2-1)th electrode 142 may be electrically connected to the (2-2)th electrode 144. The (2-1)th electrode 142 may be electrically connected to the second contact electrode CNE2 through the (2-2)th electrode 144. However, the (2-1)th electrode 142 is not limited thereto. For example, the (2-1)th electrode 142 may be electrically connected to the second contact electrode CNE2 through a contact hole formed in the first insulating layer INS1 and the contact hole may not contact (e.g., directly contact) the (2-2)th electrode 144.

The (2-2)th electrode 144 may be disposed on the (2-1)th electrode 142. The (2-2)th electrode 144 may overlap the (2-1)th electrode 142 when viewed in a plan view. A portion of the (2-2)th electrode 144 may be disposed on the second insulating pattern INP2. Accordingly, the (2-2)th electrode 144 may serve as a reflective partition wall with respect to the light emitting element LD.

The (2-2)th electrode 144 may electrically connect the second electrode ELT2 and the second contact electrode CNE2 to each other. For example, a portion of the (2-2)th electrode 144 may contact (e.g., directly contact) the (2-1)th electrode 142, and another portion of the (2-2)th electrode 144 may contact (e.g., directly contact) the second contact electrode CNE2 through a contact hole formed in the first insulating layer INS1. However, the (2-2)th electrode 144 is not limited thereto. For example, a portion of the (2-2)th electrode 144 may contact (e.g., directly contact) the (2-1)th electrode 142, and the (2-1)th electrode 142 and the second contact electrode CNE2 may be electrically connected to each other through a contact hole formed in the first insulating layer INS1.

In accordance with an embodiment, the (1-1)th electrode 122 and the (2-1)th electrode 142 may be formed through a same process. The (1-1)th electrode 122 and the (2-1)th electrode 142 may be provided by patterning an electrode component deposited at a same time.

In accordance with an embodiment, the (1-1)th electrode 122 and the (2-1)th electrode 142 may include a conductive material. For example, the (1-1)th electrode 122 and the (2-1)th electrode 142 may include a transparent conductive material. The transparent conductive material may be any one of Indium Tin Oxide (ITO), Indium Zinc Oxide (IZO), and Indium Tin Zinc Oxide (ITZO). However, the (1-1)th electrode 122 and the (2-1)th electrode 142 are not necessarily limited thereto.

In accordance with an embodiment, the (1-2)th electrode 124 and the (2-2)th electrode 144 may be formed through a same process. The (1-2)th electrode 124 and the (2-2)th electrode 144 may be provided by patterning an electrode component deposited at the same time.

In accordance with an embodiment, the (1-2)th electrode 124 and the (2-2)th electrode 144 may include a conductive material. For example, the (1-2)th electrode 124 and the (2-2)th electrode 144 may include a conductive material having reflexibility. The conductive material having reflexibility may be any one of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), and aluminum (Al). However, the (1-2)th electrode 124 and the (2-2)th electrode 144 are not limited thereto.

In accordance with an embodiment, the first contact part CNT1 electrically connected to the transistor TR may be electrically connected to the (1-1)th electrode 122 without contacting (e.g., directly contact) the (1-2)th electrode 124. Accordingly, the reliability of an electrical signal provided from the transistor TR may be improved. Similarly, the second contact part CNT2 electrically connected to the power line PL may be electrically connected to the (2-1)th electrode 142 without contacting (e.g., directly contacting) the (2-2)th electrode 144. Accordingly, the reliability of an electrical signal provided from the power line PL may be improved.

In a case that an electrode component including a reflective material (e.g., aluminum (Al) or the like) may contact (e.g., directly contact) the first contact part CNT1 or the second contact part CNT2, the resistance of the electrode component including the reflective material may increase, and the reliability of an electrical signal may be deteriorated. For example, in a case that an electrode component including aluminum (Al) is contacting (e.g., directly contact) the first contact part CNT1, an oxide layer is formed on a surface of the electrode component, and electrical resistance may be increased.

However, in accordance with an embodiment, the (1-1)th electrode 122 electrically connected to the first contact part CNT1 and the (2-1)th electrode 142 electrically connected to the second contact part CNT2 may include a transparent conductive material. Thus, an excessive increase in resistance may be prevented, and electrical reliability may be improved.

In addition to the improvement of the electrical reliability, the (1-2)th electrode 124 including a reflective material may be disposed on the (1-1)th electrode 122, and the (2-2)th electrode 144 including a reflective material may be disposed on the (2-1)th electrode 142. Thus, the light efficiency of the pixel may be improved.

The first insulating layer INS1 may be disposed on the protective layer PSV. The first insulating layer INS1 may overlap or cover the first electrode ELT1 and the second electrode ELT2. Accordingly, the first insulating layer INS1 may stabilize connection between electrode components, and reduce external influence. The first insulating layer INS1 may include any one of silicon nitride (SiNₓ), silicon oxide (SiOₓ), silicon oxynitride (SiOₓN_{y}), and aluminum oxide (AlOₓ).

The light emitting element LD may be disposed on the first insulating layer INS1. The light emitting element LD may emit light based on an electrical signal provided from the first contact electrode CNE1 and the second contact electrode CNE2.

The second insulating layer INS2 may be disposed on the light emitting element LD. The second insulating layer INS2 may overlap or cover an active layer AL (not shown) of the light emitting element LD. In an example, the second insulating layer INS2 may include at least one of an organic material and an inorganic material.

The first contact electrode CNE1 and the second contact electrode CNE2 may be disposed on the first insulating layer INS1. The first contact electrodes CNE1 may electrically connect the first electrode ELT1 and the light emitting element LD to each other, and the second contact electrode CNE2 may electrically connect the second electrode ELT2 and the light emitting element LD to each other.

The first contact electrode CNE1 and the second contact electrode CNE2 may include a conductive material. In an example, the first contact electrode CNE1 and the second contact electrode CNE2 may include a transparent conductive material including Indium Tin Oxide (ITO), Indium Zinc Oxide (IZO), and Indium Tin Zinc Oxide (ITZO), but the disclosure is not limited thereto.

The third insulating layer INS3 may overlap the first contact electrode CNE1. At least a portion of the third insulating layer INS3 may be disposed between the first contact electrode CNE1 and the second contact electrode CNE2 in a plan view such that a short circuit between the first contact electrode CNE1 and the second contact electrode CNE2 may be prevented. In accordance with an embodiment, the third insulating layer INS3 may include at least one of silicon nitride (SiNₓ), silicon oxide (SiOₓ), silicon oxynitride (SiOₓN_{y}), and aluminum oxide (AlOₓ).

The fourth insulating layer INS4 may be disposed on the display element part DPL. Accordingly, the fourth insulating layer INS4 may protect an individual component of the display element part DPL from external influence. In accordance with an embodiment, the fourth insulating layer INS4 may include at least one of silicon nitride (SiNₓ), silicon oxide (SiOₓ), silicon oxynitride (SiOₓN_{y}), and aluminum oxide (AlOₓ).

The structure of the pixel PXL is not limited thereto. In an embodiment, the pixel PXL may further include additional component.

For example, a planarization layer (not shown) may be further provided on the fourth insulating layer INS4. The planarization layer may reduce a step difference occurring due to various components disposed thereunder. A top surface of the planarization layer may be substantially flat. In accordance with an embodiment, the planarization layer may include an organic insulating layer.

In an embodiment, a color conversion layer (not shown) may be further provided on the display element part DPL. The color conversion layer may convert a specific or predetermined wavelength.

For example, the color conversion layer may include a first wavelength conversion pattern, a second wavelength conversion pattern, and a light transmission pattern. The first wavelength conversion pattern may include a first color conversion particle (e.g., a first quantum dot) for converting light emitted from the light emitting element LD into light of a first color, the second wavelength conversion pattern may include a second color conversion particle (e.g., a second quantum dot) for converting light emitted from the light emitting element LD into light of a second color, and the light transmission pattern may be configured to allow light emitted from the light emitting element LD to be transmitted therethrough. In accordance with an embodiment, an area overlapping with the first wavelength conversion pattern may be defined or formed as a first sub-pixel area, an area overlapping with the second wavelength conversion pattern may be defined or formed as a second sub-pixel area, and an area overlapping with the light transmission pattern may be defined or formed as a third sub-pixel area, so that a full-color image may be displayed.

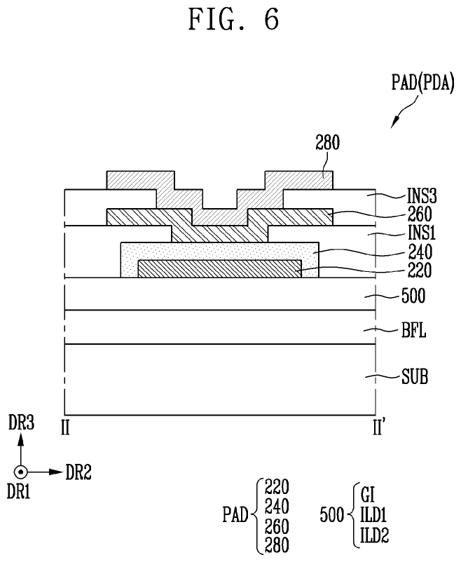

Hereinafter, a sectional structure of a pad PAD in accordance with an embodiment of the disclosure will be described with reference to FIG. 6. Hereinafter, for convenience of description, the first pad PAD1 will be described. The first pad PAD1 may be referred to as the pad PAD.

FIG. 6 is a schematic sectional view taken along line II-II' shown in FIG. 3. Referring to FIG. 6, the substrate SUB, the buffer layer BFL disposed on the substrate SUB, and a lower insulating layer 500 disposed on the buffer layer BFL may be provided or disposed in the pad area PDA. The lower insulating layer 500 may include the gate insulating layer GI, the first interlayer insulating layer ILD1, and the second interlayer insulating layer ILD2 as described above with reference to FIG. 5. In FIG. 6, same or similar components as those in FIG. 5 are denoted by the same or similar reference numerals, and thus a repeated description thereof will be omitted.

Referring back to FIG. 6, a pad PAD may be disposed in the pad area PDA. The pad PAD may include a first pad pattern 220, a second pad pattern 240, a third pad pattern 260, and a fourth pad pattern 280.

The first pad pattern 220 may be disposed in the pad area PDA. The first pad pattern 220 may be disposed on the lower insulating layer 500.

The first pad pattern 220 may be overlapped or covered by the second pad pattern 240. The second pad pattern 240 may be disposed on a side surface of the first pad pattern 220. The first pad pattern 220 may be spaced apart from the first insulating layer INS1 by the second pad pattern 240. The first pad pattern 220 may not contact the first insulating layer INS1.

The first pad pattern 220 may include a conductive material. For example, the first pad pattern 220 may include metals such as molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), aluminum (Al), and/or alloys thereof. In accordance with an embodiment, the first pad pattern 220 may be multi-layered including titanium (Ti) and copper (Cu).

In accordance with an embodiment, the first pad pattern 220 may be formed through a same process as the first transistor electrode TE1 and the second transistor electrode TE2. The first pad pattern 220, the first transistor electrode TE1, and the second transistor electrode TE2 may include a same material. For example, the first pad pattern 220 may include a same material as the first transistor electrode TE1 and the second transistor electrode TE2.

The second pad pattern 240 may be disposed in the pad area PDA. The second pad pattern 240 may be disposed on the first pad pattern 220.

The second pad pattern 240 may be electrically connected to the first pad pattern 220. One or a surface of the second pad pattern 240 may contact (e.g., directly contact) one or a surface of the first pad pattern 220. In accordance with an embodiment, an insulating layer (not shown) may be disposed between the second pad pattern 240 and the first pad pattern 220, and the second pad pattern 240 and the first pad pattern 220 may be electrically connected through a contact hole (not shown) formed in the insulating layer.

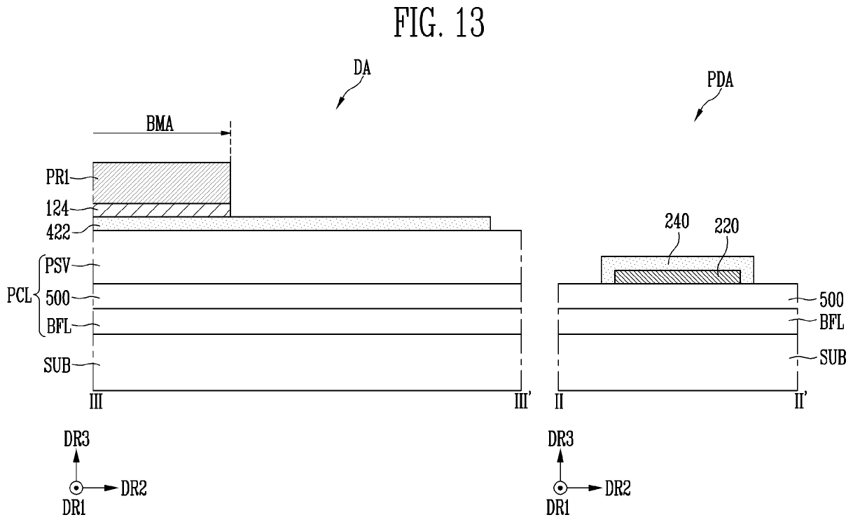

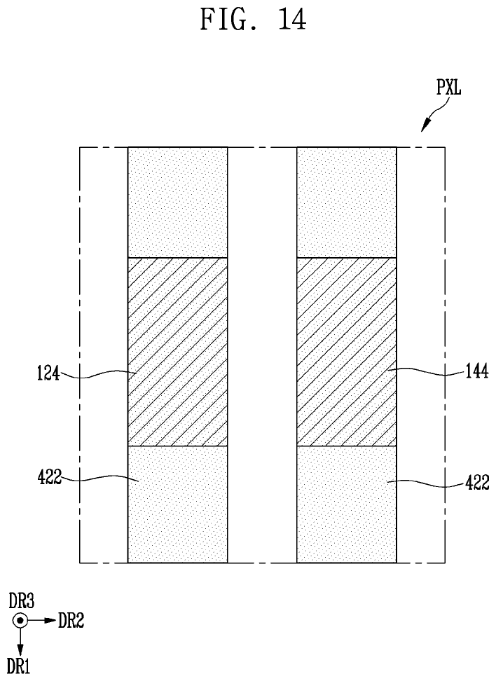

The second pad pattern 240 may overlap or cover the one surface of the first pad pattern 220. For example, the second pad pattern 240 may cap (or cover) the first pad pattern 220 such that the side surface of the first pad pattern 220 may not be exposed. Accordingly, external influence on the first pad pattern 220 while a process is performed may be reduced. This will be described in detail with reference to FIG. 13.

The second pad pattern 240 may include a transparent conductive material. For example, the second pad pattern 240 may include any one of Indium Tin Oxide (ITO), Indium Zinc Oxide (IZO), and Indium Tin Zinc Oxide (ITZO).

In accordance with an embodiment, the second pad pattern 240 may be formed through a same process as the (1-1)th electrode 122 and the (2-1)th electrode 142. The second pad pattern 240, the (1-1)th electrode 122, and the (2-1)th electrode 142 may have a same material. For example, the second pad pattern 240 may include a same material as the (1-1)th electrode 122 and the (2-1)th electrode 142.

The third pad pattern 260 may be disposed in the pad area PDA. The third pad pattern 260 may be disposed on the second pad pattern 240.

The third pad pattern 260 may be electrically connected to the second pad pattern 240. One or a surface of the third pad pattern 260 may contact (e.g., directly contact) the other or another surface of the second pad pattern 240. In accordance with an embodiment, a portion of the first insulating layer INS1 may be disposed between the third pad pattern 260 and the second pad pattern 240. The third pad pattern 260 and the second pad pattern 240 may be electrically connected to each other through a contact hole formed in the first insulating layer INS1.

The third pad pattern 260 may include a transparent conductive material. For example, the third pad pattern 260 may include any one of Indium Tin Oxide (ITO), Indium Zinc Oxide (IZO), and Indium Tin Zinc Oxide (ITZO).

In accordance with an embodiment, the third pad pattern 260 may be formed through a same process as the first contact electrode CNE1. The third pad pattern 260 and the first contact electrode CNE1 may include a same material. For example, the third pad pattern 260 may include a same material as the first contact electrode CNE1.

The fourth pattern 280 may be disposed in the pad area PDA. The fourth pad pattern 280 may be disposed on the third pad pattern 260.

The fourth pad pattern 280 may be electrically connected to the third pad pattern 260. One or a surface of the fourth pad pattern 280 may contact (e.g., directly contact) the other or another surface of the third pad pattern 260. In accordance with an embodiment, a portion of the third insulating layer INS3 may be disposed between the fourth pad pattern 280 and the third pad pattern 260, and the fourth pad pattern 280 and the third pad pattern 260 may be electrically connected to each other through a contact hole formed in the third insulating layer INS3.

The fourth pad pattern 280 may include a transparent conductive material. For example, the fourth pad pattern 280 may include any one of Indium Tin Oxide (ITO), Indium Zinc Oxide (IZO), and Indium Tin Zinc Oxide (ITZO).

In accordance with an embodiment, the fourth pad pattern 280 may be formed through a same process as the second contact electrode CNE2. The fourth pad pattern 280 and the second contact electrode CNE2 include a same material. For example, the fourth pad pattern 280 may include a same material as the second contact electrode CNE2.

In accordance with an embodiment, the pad PAD may further include additional layer. For example, the pad PAD may further include a gate pad pattern (not shown) provided or disposed through a same process as the gate electrode GE. The gate pad pattern may be disposed farther to the substrate SUB than the first pad pattern 220, and may be electrically connected to the first pad pattern 220. The gate pad pattern and the gate electrode GE may include a same material. For example, the gate pad pattern may include a same material as the gate electrode GE.

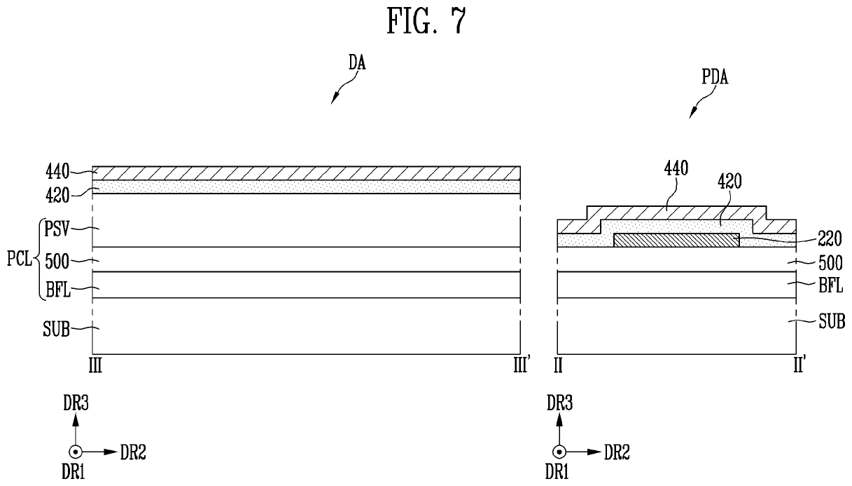

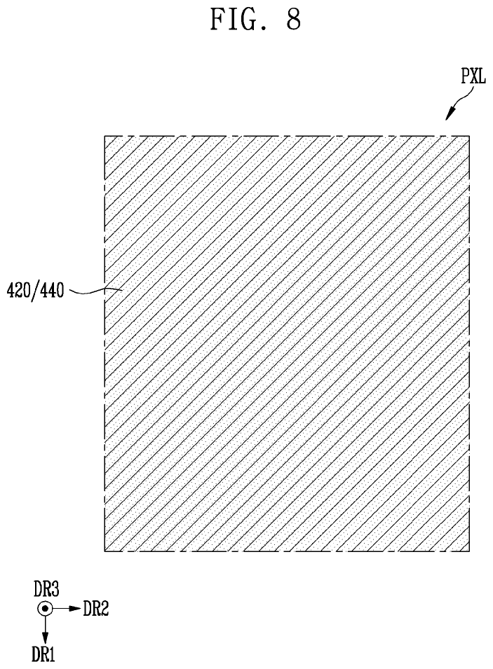

Hereinafter, a manufacturing method of the display device in accordance with an embodiment will be described with reference to FIGS. 7 to 18. Descriptions of portions similar with those described above will be simplified or omitted.

FIGS. 7, 9, 10, 12, 13, 15, 17, and 19 are schematic sectional views illustrating a manufacturing method of the display device in accordance with an embodiment. FIGS. 7, 9, 10, 12, 13, 15, 17, and 19 are schematic sectional views of the display device during a manufacturing process in accordance with an embodiment, and a schematic sectional view taken along line III-III' shown in FIG. 4 and a schematic sectional view taken along line II-II' shown in FIG. 2 will be illustrated. FIGS. 7, 9, 10, 12, 13, 15, 17, and 19 are schematic views illustrating a stacked structure of a display area DA and a pad area PDA.

FIGS. 8, 11, 14, 16, and 18 are schematic plan views illustrating the manufacturing method of the display device in accordance with an embodiment. FIGS. 8, 11, 14, 16, and 18 are schematic views illustrating a planar structure during the manufacturing process of the display device in accordance with an embodiment, and an area of the pixel PXL shown in FIG. 4. FIGS. 8, 11, 14, 16, and 18 are schematic views illustrating a state in which electrode components are disposed in the display area DA.

Referring to FIGS. 7 and 8, a substrate SUB may be provided, a pixel circuit part PCL may be disposed on the substrate SUB in the display area DA, and insulating layers may be disposed on the substrate SUB in the pad area PDA. A base lower electrode 420 and a base upper electrode 440 may be formed or disposed in each of the display area DA and the pad area PDA.

In a step, individual components of the pixel circuit part PCL disposed on the substrate SUB may be formed by patterning a conductive layer (or metal layer), an inorganic material, an organic material, or the like through a process using a mask.

In a step, a buffer layer BFL may be disposed on the substrate SUB, a lower insulating layer 500 may be disposed on the buffer layer BFL, and a protective layer PSV may be disposed on the lower insulating layer 500 in the display area DA. In accordance with an embodiment, the buffer layer BFL and the lower insulating layer 500 may be insulating layers provided or disposed in the pixel circuit part PCL in the display area DA, and simultaneously, provided or disposed on a bottom surface of a first pad pattern 220 in the pad area PDA.

In a step, although not shown, a first transistor electrode TE1 and a second transistor electrode TE2 may be disposed on the lower insulating layer 500 in the display area DA.

In a step, the first pad pattern 220 may be disposed on the lower insulating layer 500 in the pad area PDA. The first pad pattern 220 may be patterned through a same process as the first and second transistor electrodes TE1 and TE2 of a transistor TR (not shown in FIG. 7 formed in the display area DA.

In a step, the base lower electrode 420 and the base upper electrode 440 may be deposited on an entire surface of the display area DA (see FIG. 8) and the pad area PDA. For example, the base lower electrode 420 in the display area DA may be deposited on the protective layer PSV, and the base lower electrode 420 in the pad area PDA may be deposited on the lower insulating layer 500.

In a step, the base lower electrode 420 in the pad area PDA may be provided after the first pad pattern 220 is formed. The base lower electrode 420 may contact (e.g., directly contact) the first pad pattern 220. Accordingly, the first pad pattern 220 may be capped (or covered by the base lower electrode 420, and the first pad pattern 220 may not be exposed by the base lower electrode 420.

In a step, the base lower electrode 420 may be electrically connected to the transistor TR (e.g., the first transistor electrode TE1).

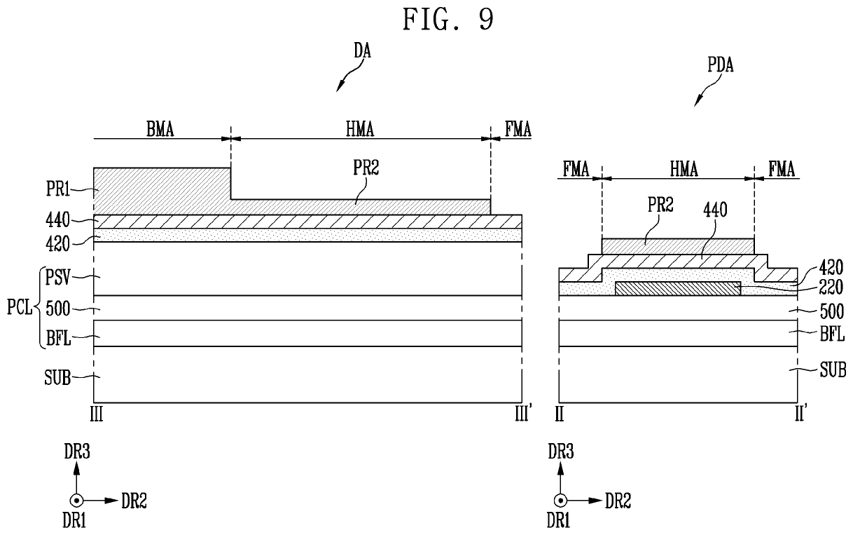

Referring to FIG. 9, a base photoresist layer may be deposited on the entire surface of the display area DA and the pad area PDA. The deposited base photoresist layer may be patterned by using a mask including a half-tone part, a full-tone part, and a blocking part. The base photoresist layer may include a first photoresist layer PR1 and a second photoresist layer PR2.

In accordance with an embodiment, the base photoresist layer may include a photosensitive material.

In a step, a portion of the base photoresist layer in a half-tone area HMA may be removed. The half-tone area HMA may be an area corresponding to the half-tone part of the mask during a photo process using the mask. A light transmittance at the half-tone part may be lower than that at the full-tone part, and be higher than that of the blocking part.

In a step, the base photoresist layer in a full-tone area FMA may be removed. The full-tone area FMA may be an area corresponding to the full-tone part of the mask during the photo process using the mask. A light transmittance at the full-tone part may be higher than that at the half-tone part. In the full-tone area FMA, the base upper electrode 440 may be exposed.

In a step, the base photoresist layer in a blocking area BMA may not be removed. The blocking area BMA may be an area corresponding to the blocking part of the mask during the photo process using the mask. Light at the blocking part may be substantially blocked.

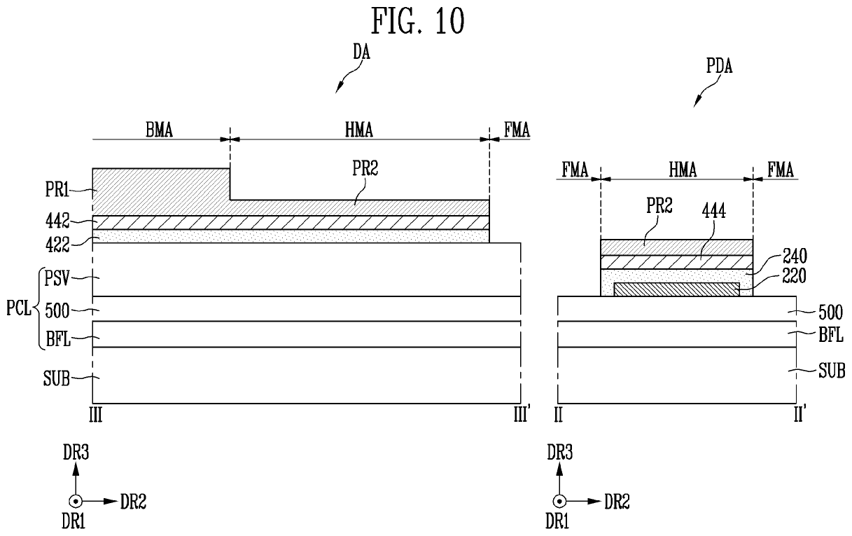

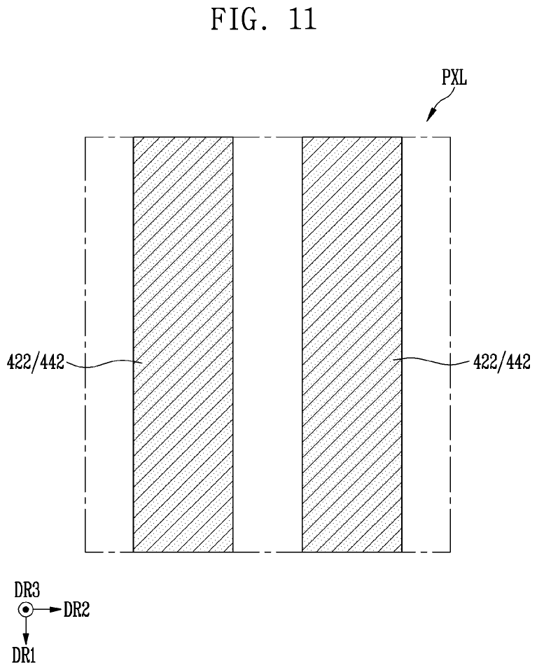

Referring to FIGS. 10 and 11, a portion of the base lower electrode 420 and the base upper electrode 440 may be removed, thereby providing a lower electrode 422 and an upper electrode 442 in the display area DA, and providing a second pad pattern 240 and a residual electrode 444 in the pad area PDA. This step may be referred to as a first etching step.

During the first etching step, the base lower electrode 420 and the base upper electrode 440 may be etched by using the first photoresist layer PR1 and the second photoresist layer PR2 as an etching mask.

For example, the base lower electrode 420 and the base upper electrode 440 that disposed in the full-tone area FMA may be removed. Accordingly, the protective layer PSV in the display area DA and the lower insulating layer 500 in the pad area PDA may be exposed.

As shown in FIG. 11, the lower electrode 422 and the upper electrode 442 may extend in the first direction DR1. The lower electrode 422 and the upper electrode 442 may overlap with each other when viewed in a plan view. The lower electrode 422 and the upper electrode 442 may be components for providing a first electrode ELT1 and a second electrode ELT2 as a subsequent process is performed.

For example, the second pad electrode 240 and the residual electrode 444 in the pad area PDA may overlap the half-tone area HMA when viewed in a plan view. In accordance with an embodiment, the residual electrode 444 may be disposed on the second pad pattern 240.

During the first etching step, a portion of the base lower electrode 420 in the pad area PDA may be removed, and a portion of the base lower electrode 420 adjacent to the first pad pattern 220 may not be removed.

For example, the half-tone area HMA in the pad area PDA may be formed wider than an area where the first pad pattern 220 is disposed. The first pad pattern 220 may be located or disposed in the half-tone area HMA when viewed in a plan view. Accordingly, the base lower electrode 420 disposed in an area corresponding to the half-tone area HMA may not be removed, accordingly, at least a portion of the second pad pattern 240 may be provided to overlap or cover a side surface of the first pad pattern 220. Accordingly, the first pad pattern 220 may be overlapped or covered by the second pad pattern 240 such that influence from the outside may be reduced.

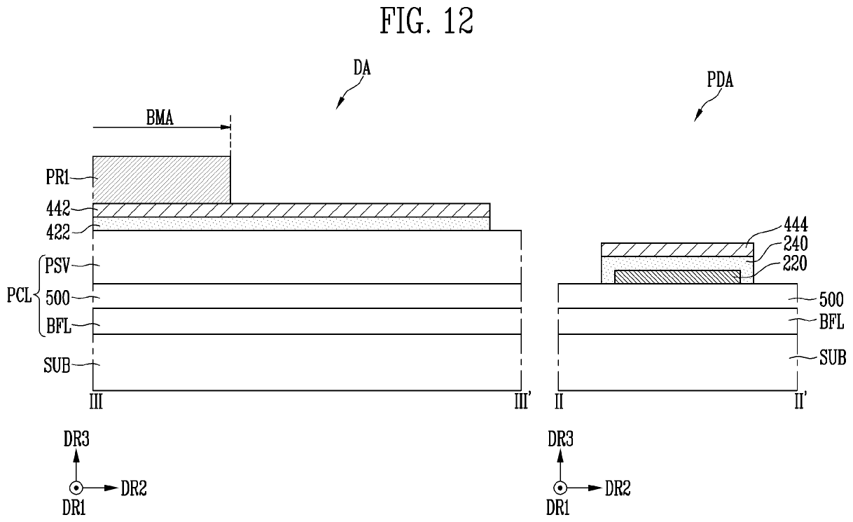

Referring to FIG. 12, the second photoresist layer PR2 disposed in the half-tone area HMA may be removed. Accordingly, after the second photoresist layer PR2 is removed, the first photoresist layer PR1 disposed in the blocking area BMA may remain. For example, only the first photoresist layer PR1 disposed in the blocking area BMA may remain.

During the removing of the second photoresist layer 2, the upper electrode 442 in the display area DA and the residual electrode 444 in the pad area PDA may be exposed by performing an ashing process on the second photoresist layer PR2.

Referring to FIGS. 13 and 14, a (1-2)th electrode 124 and a (2-2)th electrode 144 in the display area DA may be provided by removing a portion of the upper electrode 442. The second pad pattern 240 in the pad area PDA may be exposed by removing the residual electrode 444. This step may be referred to as a second etching step.

For example, the upper electrode 442 and the residual electrode 444 may be removed through wet etching.

For example, the upper electrode 442 disposed in the half-tone area HMA may be removed. Accordingly, the lower electrode 422 disposed in the half-tone area HMA in the display area DA may be exposed.

For example, the residual electrode 444 disposed on the pad area PDA may be removed. In accordance with an embodiment, the first pad pattern 220 may be overlapped or covered by the second pad pattern 240. Accordingly, damage of the first pad pattern 220 which may occur during a wet etching process for removing the residual electrode 444 may be prevented.

In accordance with an embodiment, after the upper electrode 442 and the residual electrode 444 are removed, the first photoresist layer PR1 may be removed. In an example, the first photoresist layer PR1 may be removed by performing a strip process.

Subsequently, although not shown, a light emitting element LD may be disposed. In accordance with an embodiment, the light emitting element LD may be arranged or disposed by providing or disposing an ink including the light emitting element LD and a solvent on the substrate SUB and forming an electric field.

For example, an external force (e.g., a DEP force) may be applied to the light emitting element LD by providing an electrical signal (e.g., an AC signal) to the lower electrode 422, the (1-2)th electrode 124, and the (2-2)th electrode 144 that may be adjacent to an area where the light emitting element LD may be arranged or disposed. The light emitting element LD may be arranged or disposed by the external force.

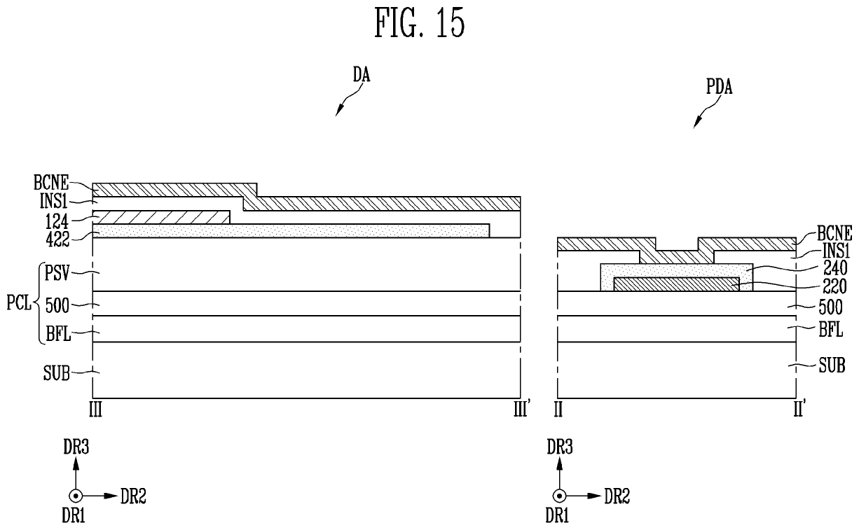

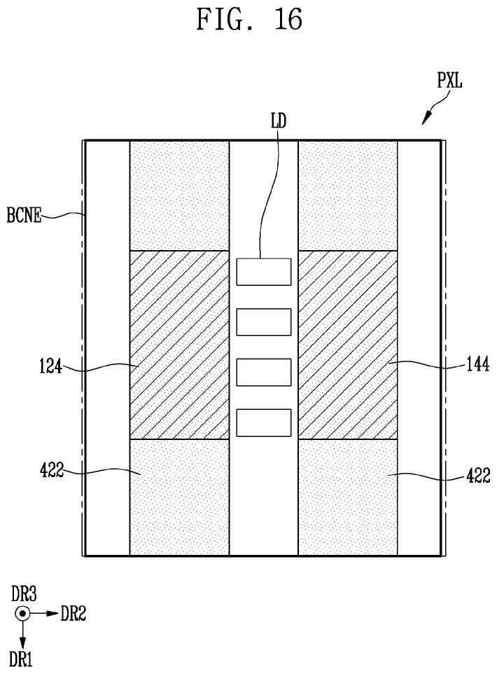

Referring to FIGS. 15 and 16, a base contact electrode BCNE may be formed or disposed in each of the display area DA and the pad area PDA.

In accordance with an embodiment, before the BCNE is disposed on the display area DA and the pad area PDA, a first insulating layer INS1 may be formed (or deposited). The first insulating layer INS1 may be provided or disposed to overlap or cover the lower electrode 422, the (1-2)th electrode 124, the (2-2)th electrode 144, and the second pad pattern 240. A portion of the second pattern 240 in the pad area PDA may be exposed by removing a portion of the first insulating layer INS1.

For example, the base contact electrode BCNE may be deposited on the entire surface of the display area DA and the pad area PDA.

Although not shown, the base contact electrode BCNE in the display area DA may be electrically connected to the (1-2)th electrode 124 and/or the lower electrode 422.

Referring to FIG. 15, the base contact electrode BCNE in the pad area PDA may be electrically connected to the second pad pattern 240.

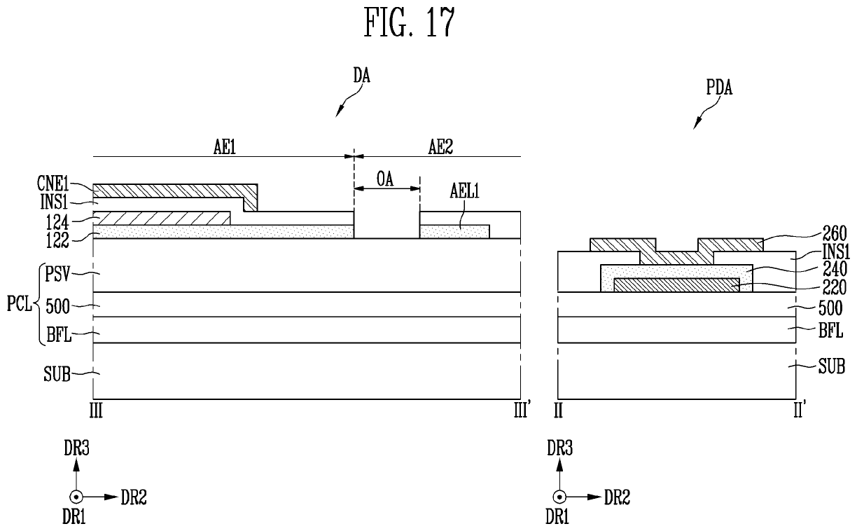

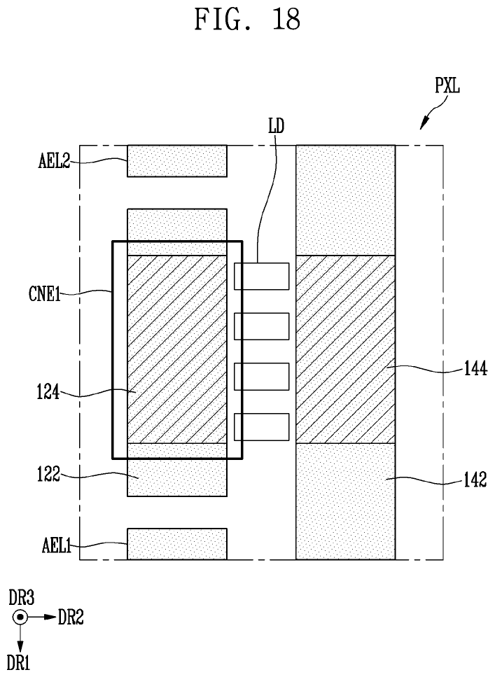

Referring to FIGS. 17 and 18, a first contact electrode CNE1 and a third pad pattern 260 may be provided by removing a portion of the base contact electrode BCNE such that an open area OA may be provided. This step may be referred to as a third etching step.

In accordance with an embodiment, the base contact electrode BCNE may be etched through wet etching.

For example, a portion of the base contact electrode BCNE in the pad area PDA may be removed and an area where the portion of the based contact electrode BCNE is removed may not overlap the second pad pattern 240 when viewed in a plan view.

Accordingly, an alignment area AE1 and a non-alignment area AE2 may be provided by removing at least a portion of the base contact electrode BCNE. The alignment area AE1 relates to an area where the light emitting element LD may be arranged or disposed, and may be distinguished from the non-alignment area AE2 by one or an end of the open area OA.

The base contact electrode BCNE and the lower electrode 422 may be collectively or simultaneously etched. For example, an area where the lower electrode 422 is etched to provide the open area OA may overlap with an area where the base contact electrode BCNE in the display area DA is etched when viewed in a plan view.

Accordingly, the open area OA may be provided by removing at least a portion of the base contact electrode BCNE. In order to provide the open area OA, a portion of the lower electrode 422 may be removed, and electrode components electrically separated from each other may be provided.

For example, as the open area OA may be provided by removing the portion of the lower electrode 422, a (1-1)th electrode 122, a (2-1)th electrode 142, a first adjacent electrode AEL1, and a second adjacent electrode AEL2 may be provided.

In order to implement individual driving of sub-pixels, it may be necessary to distinguish a path through which an electrical signal between adjacent sub-pixels is applied. Accordingly, a process including etching for providing the open area OA, and the like may be performed.

In accordance with an embodiment, an etching process for providing the open area OA and an etching process for the first contact electrode CNE1 may be collectively or simultaneously performed, thereby the number of process steps may be decreased. Accordingly, processing procedure may be simplified, and thus process cost may be reduced.

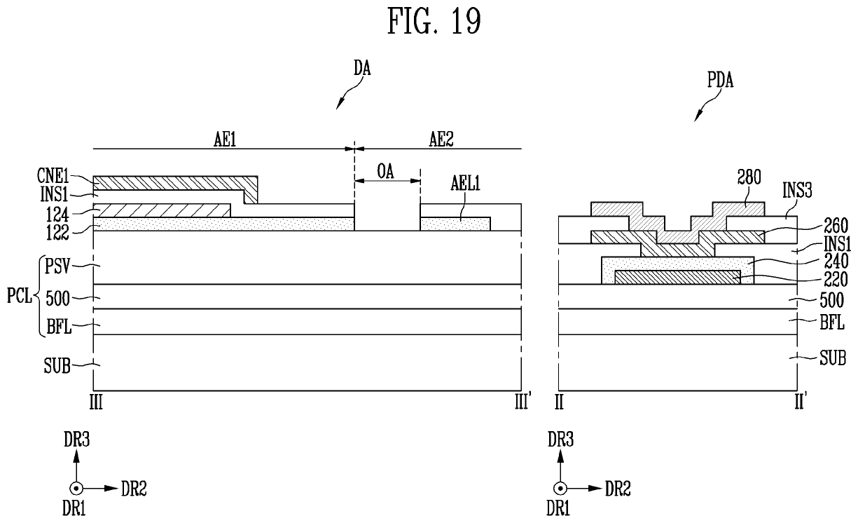

Referring to FIG. 19, a fourth pad pattern 280 may be formed or disposed on the third pad pattern 260 in the pad area PDA, thereby providing the pad PAD in accordance with an embodiment.

For example, although not shown, a base contact electrode may be formed (or deposited) on the entire surface of the display area DA and the pad area PDA, and a portion of the base contact electrode may be removed. For example, a portion of the base contact electrode in the display area DA may be removed, thereby a second contact electrode CNE2 may be provided, and a portion of the base contact electrode in the pad area PDA may be removed, thereby the fourth pad pattern 280 may be provided.

Referring to FIG. 19, the fourth pad pattern 280 may be electrically connected to the third pad pattern 260 with a third insulating layer INS3 interposed therebetween.

Subsequently, although not shown, a fourth insulating layer INS4 may be formed or disposed, thereby a display element part DPL may be provided in accordance with an embodiment. However, the disclosure is not limited thereto. For example, additional component (e.g., a color conversion layer, or the like) may be disposed.

In accordance with the disclosure, a pad structure, a display device, and a manufacturing method thereof in which the reliability of an electrical signal may be improved, and the structural stability of an electrode configuration may be ensured.

In accordance with the disclosure, a pad structure, a display device, and a manufacturing method thereof in which process steps may be simplified, and thus process cost may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device including a display area and a pad area, the display device comprising:
a first electrode and a second electrode disposed on a substrate in the display area, the first electrode and the second electrode being spaced apart from each other;
a transistor disposed on the substrate in the display area, the transistor being electrically connected to the first electrode, and including a first transistor electrode and a second transistor electrode;
a light emitting element disposed on the first electrode and the second electrode; and
a pad structure disposed on the substrate in the pad area, the pad structure including a first pad pattern and a second pad pattern disposed on the first pad pattern, the second pad pattern being electrically connected to the first pad pattern, wherein
the first electrode includes a (1-1)th electrode and a (1-2)th electrode disposed on the (1-1)th electrode,
the second electrode includes a (2-1)th electrode and a (2-2)th electrode disposed on the (2-1)th electrode,
the first pad pattern, the first transistor electrode, and the second transistor electrode include a same material,
the second pad pattern, the (1-1)th electrode, and the (2-1)th electrode include a same material, and
the (1-1)th electrode and the (2-1)th electrode include a transparent conductive material.

2. The display device of claim 1, further comprising:
a power line disposed on the substrate, the power line supplying power to the light emitting element, wherein
the (1-1)th electrode is electrically connected to the transistor through a first contact part which does not contact the (1-2)th electrode, and
the (2-1)th electrode is electrically connected to the power line through a second contact part which does not contact the (2-2)th electrode.

3. The display device of claim 2, wherein the (1-2)th electrode and the (2-2)th electrode include a reflective material and reflect light emitted from the light emitting element.

4. The display device of claim 1, further comprising:
a first contact electrode electrically connecting the first electrode and the light emitting element; and
a second contact electrode electrically connecting the second electrode and the light emitting element, wherein
the first contact electrode is electrically connected to the (1-1)th electrode, and
the second contact electrode is electrically connected to the (2-1)th electrode.

5. The display device of claim 1, wherein the first transistor electrode, the second transistor electrode, and the first pattern include at least one of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), aluminum (Al), and alloys thereof.

6. The display device of claim 1, wherein:
the second pad pattern includes a material different from a material of the (1-2)th electrode and a material of the (2-2)th electrode, and
the (1-1)th electrode, the (2-1)th electrode, and the second pad pattern include at least one of Indium Tin Oxide (ITO), Indium Zinc Oxide (IZO), and Indium Tin Zinc Oxide (ITZO).

7. The display device of claim 1, wherein the second pad pattern covers a side surface of the first pad pattern such that the first pad pattern is not exposed.

8. The display device of claim 4, further comprising:
a third pad pattern electrically connected to the second pad pattern, the third pad pattern being disposed on the second pad pattern; and
a fourth pad pattern electrically connected to the third pattern, the fourth pad pattern being disposed on the third pad pattern, wherein
the first contact electrode and the third pad pattern include a same material, and
the second contact electrode and the fourth pad pattern include a same material.

9. The display device of claim 1, further comprising:
an alignment area including an area in which the light emitting element is disposed; and
a non-alignment area including an area in which the light emitting element is not disposed, wherein
the first electrode and the second electrode extend in a first direction,
the alignment area and the non-alignment area overlap each other in the first direction,
the (1-1)th electrode and the (1-2)th electrode overlap each other in the alignment area and do not overlap each other in the non-alignment area in a plan view, and
the (2-1)th electrode and the (2-2)th electrode overlap each other in the alignment area and do not overlap each other in the non-alignment area in a plan view.

10. The display device of claim 9, further comprising an open area disposed in the non-alignment area,
wherein the first electrode and the second are not disposed in the open area.

11. A pad structure comprising:
a first pad pattern disposed on a substrate; and
a second pad pattern electrically connected to the first pad pattern, the second pad pattern being disposed on the first pad pattern, wherein
the second pad pattern includes a transparent conductive material and covers a side surface of the first pad pattern such that the first pad pattern is not exposed.

12. The pad structure of claim 11, further comprising:
a third pad pattern electrically connected to the second pad pattern, the third pad pattern being disposed on the second pad pattern; and
a fourth pad pattern electrically connected to the third pattern, the fourth pad pattern being disposed on the third pad pattern, wherein
the third pad pattern and the fourth pad pattern include a transparent conductive material.

13. A method of manufacturing a display device including a display area and a pad area, the method comprising:
disposing a lower insulating layer on a substrate;
disposing a first transistor electrode and a second transistor electrode on the lower insulating layer in the display area;
disposing a first pad pattern on the lower insulating layer in the pad area;
disposing a base lower electrode and a base upper electrode on the lower insulating layer;
removing at least part of each of the base lower electrode and the base upper electrode; and
disposing a light emitting element on the substrate, wherein
the removing of the at least part of each of the base lower electrode and the base upper electrode includes:
forming a first photoresist layer in a blocking area corresponding to a blocking part of a mask,
forming a second photoresist layer in a half-tone area corresponding to a half-tone part of the mask,
exposing the base upper electrode in a full-tone area corresponding to a full-tone part of the mask;
a first etching step of etching the base lower electrode and the base upper electrode in the full-tone area; and
a second etching step of etching the base upper electrode in the half-tone area, and
the disposing of the first transistor electrode and the second transistor electrode and the disposing of the first pad pattern are performed through a same process, and
the first etching step includes disposing a second pad pattern on the first pad pattern, the second pad pattern being electrically connected to the first pad pattern.

14. The method of claim 13, wherein
the second etching step includes disposing a lower electrode in the display area, and
the method further comprises:
disposing a base contact electrode on the lower electrode after the second etching step; and
simultaneously etching the base contact electrode and the lower electrode.

15. The method of claim 14, wherein the simultaneously etching of the base contact electrode and the lower electrode includes providing an open area in which the lower electrode is not disposed.

16. The method of claim 13, wherein
the disposing of the base lower electrode and the base upper electrode includes disposing the base lower electrode to cover the first pad pattern, and
in the first etching step, at least part of the base lower electrode disposed on a side surface of the first pad pattern is not etched.

17. The method of claim 16, wherein the second pad pattern covers the first pad pattern such that effect of the second etching step on the first pad pattern is decreased.

18. The method of claim 13, wherein the disposing of the first transistor electrode and the second transistor electrode and the disposing of the first pad pattern are performed through a same process.

19. The method of claim 13, wherein the disposing of the base lower electrode includes electrically connecting the transistor and the base lower electrode to each other.

20. The method of claim 14, wherein the disposing of the light emitting element includes:
providing, on the substrate, an ink including the light emitting element and a solvent;
forming an electric field by applying an electrical signal to the lower electrode; and
arranging the light emitting element in accordance with the electric field.
